(19) United States
(12) Patent Application Publication
(10) Pub. No.: US 2024/0258769 A1
(43) Pub. Date: Aug. 1, 2024

(54) EXTERNAL CAVITY LASING AND ON-CHIP SELF-INJECTION LOCKING BASED ON CASCADED GRATING STRUCTURES

(71) Applicant: Honeywell International Inc., Charlotte, NC (US)

(72) Inventors: Matthew Wade Puckett, Phoenix, AZ (US); Neal Eldrich Solmeyer, Edina, MN (US); Karl D. Nelson, Plymouth, MN (US); Jianfeng Wu, Tucson, AZ (US); Mary Salit, Plymouth, MN (US)

(73) Assignee: Honeywell International Inc., Charlotte, NC (US)

(21) Appl. No.: 18/162,517

(22) Filed: Jan. 31, 2023

(51) Int. Cl. H01S 5/14; H01S 3/10; H01S 5/10; H01S 5/12; H01S 5/323

(52) U.S. Cl. CPC H01S 5/141; H01S 3/10092; H01S 5/1007; H01S 5/12; H01S 5/323; H01S 5/50

(57) ABSTRACT

A laser device comprises a gain chip that emits light, and a photonics chip optically coupled to the gain chip. The photonics chip comprises a waveguide platform including an input waveguide optically coupled to the gain chip. The input waveguide optical communicates with a cascaded arrangement of waveguide grating structures on the waveguide platform. The grating structures comprise a first grating structure that produces a single resonance frequency within a stopband, and a second grating structure in optical communication with the first grating structure. The second grating structure diffracts a narrowband resonance, overlapping with the stopband of the first grating structure, back toward the gain chip, while passing any light outside of the stopband of the first grating structure out of the waveguide platform. The grating structures cooperate to yield a single resonance frequency that feeds back into the gain chip to produce a self-injection lock for the laser device.

### STATEMENT REGARDING FEDERALLY SPONSORED RESEARCH OR DEVELOPMENT

This invention was made with Government support under FA8650-20-C-7034 awarded by Air Force Research Laboratory. The Government has certain rights in the invention.

### BACKGROUND

In optics and photonics, self-injection locking is a powerful effect that allows a laser's wavelength of emission to be locked to that of an external resonator. This locking effect is often accompanied by a drastic reduction in the linewidth of the laser, which can be useful in many applications. Additionally, automatically locking the wavelength of emission to a resonator can facilitate the generation of desirable nonlinear effects in the resonator, such as stimulated Brillouin scattering and optical frequency generation.

A magnetometer can also be produced in a self-injection locked laser by integrating diamond crystals with nitrogen vacancies, which may exhibit a loss coefficient that is sensitive to the local magnetic field, into the device. Several architectures exist for the implementation of self-injection locking, and a key requirement of these architectures is that the external feedback provided by the chip does not support multi-mode lasing, which can hurt power efficiency.

In prior approaches, single frequency feedback is achieved by cascading two ring resonators in series and employing the Vernier effect to shift their aligned resonances with each other. However, this technique requires significant space on the chip, setting a lower limit on the size of the consequent device. Aligning resonances from the two rings resonators can additionally pose a significant technical challenge, and requires active control of the temperature of one or both of the resonators, adding complexity to the operation of the device.

### SUMMARY

A laser device comprises a gain chip configured to emit a beam of light, and a photonics chip optically coupled to the gain chip. The photonics chip comprises a waveguide platform including an input waveguide, which is optically coupled to the gain chip. The input waveguide is in optical communication with a cascaded arrangement of waveguide grating structures on the waveguide platform. The waveguide grating structures comprise a first waveguide grating structure configured to produce a single resonance frequency within a stopband, and a second waveguide grating structure in optical communication with the first waveguide grating structure. The second waveguide grating structure is configured to diffract a narrowband resonance, overlapping with the stopband of the first waveguide grating structure, back toward the gain chip, while passing any light outside of the stopband of the first waveguide grating structure out of the waveguide platform. The first and second waveguide grating structures cooperate to yield a single resonance frequency of the light that feeds back into the gain chip to produce a self-injection lock for the laser device.

### BRIEF DESCRIPTION OF THE DRAWINGS

Features of the present invention will become apparent to those skilled in the art from the following description with reference to the drawings. Understanding that the drawings depict only typical embodiments and are not therefore to be considered limiting in scope, the invention will be described with additional specificity and detail through the use of the accompanying drawings, in which:

FIG. 1 is a schematic top view of an external cavity laser device, according to one embodiment;

FIG. 2 is an enlarged perspective view of a pi phase shift design for a waveguide grating structure including a single defect cavity, according to one embodiment, which can be employed in the external cavity laser device of FIG. 1;

FIG. 3A is a graphical representation of a transmission spectrum of a light beam in a single defect cavity, which can be employed in the external cavity laser device of FIG. 1; and

FIG. 3B is a graphical representation of a reflection spectrum of a light beam in a filter grating, which can be employed in the external cavity laser device of FIG. 1.

### DETAILED DESCRIPTION

In the following detailed description, embodiments are described in sufficient detail to enable those skilled in the art to practice the invention. It is to be understood that other embodiments may be utilized without departing from the scope of the invention. The following detailed description is, therefore, not to be taken in a limiting sense.

An architecture for external cavity lasing and on-chip self-injection locking based on cascaded waveguide grating structures, is described herein.

In the present approach, shortcomings of prior techniques for self-injection locking are overcome by using a single defect cavity in a first grating structure on-chip to produce a single resonance within a stopband. On the same chip, a second grating structure is included to diffract only the narrow resonance back toward a gain chip, while passing any light outside the stopband of the first grating structure out of an optical circuit. The two grating structures, combined in series, yield a single narrow resonance that feeds back into the gain chip, producing a reliable self-injection lock, and the narrowness of the resonance is limited only by the loss of the waveguide platform.

The present architecture can be implemented without the need to thermally tune either of the grating structures, making the device easy to operate. The architecture is additionally pseudo-one-dimensional, allowing for very small device footprints and a very high degree of scalability.

The present device architecture can be fabricated using one of several integrated photonics fabrication processes, which can employ an ultra-low loss silicon nitride waveguide platform, for example. In the definition of the waveguide layer, an input waveguide is included, which may be accessed by a laser diode or gain chip. The input waveguide is split such that half of the optical power is routed between two other waveguides. Following one arm of the device, the waveguide enters into a first waveguide grating structure, such as single defect cavity Bragg grating resonator comprised of a first grating-assisted contradirectional coupler with a pi phase shift. A transmission port of the first waveguide grating structure is routed to a second waveguide grating structure, such as a Bragg grating filter, comprised of a second grating-assisted contradirectional coupler. A reflection port of the second waveguide grating structure is routed back to the split of the input waveguide, forming a closed loop.

The present device architecture results in an optical circuit that only reflects a narrow band of the optical spectrum back into the gain chip through a closed loop, producing an optimal feedback for self-injection locking and external cavity lasing.

Further details regarding the present approach are described as follows and with reference to the drawings.

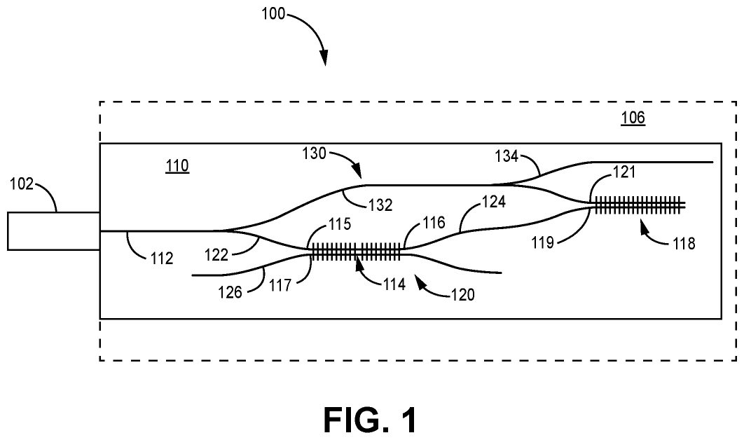

FIG. 1 is a schematic illustration of an architecture for an external cavity laser device 100, according to one embodiment. The laser device 100 generally includes a gain chip 102 configured to emit a light beam, and a photonics chip 106 optically coupled to gain chip 102. The gain chip 102 can be a reflective semiconductor optical amplifier (RSOA), such as an indium phosphide (InP) based RSOA, and photonics chip 106 can be a silicon photonics integrated circuit, for example.

The photonics chip 106 comprises a waveguide platform 110, which includes an input waveguide 112 that is optically coupled to gain chip 102. The input waveguide 112 is in optical communication with a cascaded arrangement of a first waveguide grating structure 114, and a second waveguide grating structure 118, on waveguide platform 110. The first waveguide grating structure 114 includes a single defect cavity, such as a single defect cavity Bragg grating, configured to operate as a resonator. The second waveguide grating structure 118 is a filter grating. such as a Bragg filter grating.

As described further hereafter, first waveguide grating structure 114 can be implemented as a grating-assisted contradirectional coupler that has a periodic grating structure, with a pi phase shift in a central portion thereof. The second waveguide grating structure 118 can similarly be implemented as a grating-assisted contradirectional coupler that has a periodic grating structure, but without the pi phase shift. The pi phase shift in first waveguide grating structure 114 produces a narrow transmission band in the center of a stopband.

As shown in FIG. 1, input waveguide 112 is split between a first waveguide arm 120 and a second waveguide arm 130, such as with a Y-splitter, on waveguide platform 110. The first waveguide arm 120 comprises first waveguide branch 122 coupled between input waveguide 112 and an input port 115 of first waveguide grating structure 114; a second waveguide branch 124 coupled between a transmission port 116 of first waveguide grating structure 114 and an input port 119 of second waveguide grating structure 118; and a third waveguide branch 126 coupled with a reflection port 117 of first waveguide grating structure 114. The second waveguide arm 130 comprises a fourth waveguide branch 132 coupled between input waveguide 112 and a reflection port 121 of second grating structure 118; and a fifth waveguide branch 134, split off from fourth waveguide branch 132, and directed to a laser output.

The first waveguide grating structure 114 is configured to produce a single resonance frequency of the light beam within a stopband. The second waveguide grating structure 116 is configured to diffract a narrowband resonance of the light beam, overlapping with the stopband of first waveguide grating structure 114, back toward gain chip 102, while passing any light outside of the stopband of first waveguide grating structure 114 out of waveguide platform 110. The first and second waveguide grating structures 114, 118 operate together to yield a single resonance frequency of the light beam that feeds back into gain chip 102, producing a self-injection lock for laser device 102.

The waveguide platform 110 can include a substrate layer coupled to photonics chip 106, a cladding layer over the substrate layer, and a waveguide layer over the cladding layer. The waveguide layer defines the cascaded arrangement of waveguide grating structures 114, 118 with the interconnecting waveguide branches. In an example embodiment, the substrate layer can be a silicon substrate, the cladding layer can be a silicon dioxide cladding, and the waveguide layer can be a silicon nitride layer.

The waveguide platform 110 can be produced by fabricating a photonics waveguide such as by using one of several well-established integrated photonics fabrication processes known to those skilled in the art. In fabricating waveguide platform 110, a substrate is provided, such as an initial wafer, which can also include underlying handle wafer. A cladding material is then deposited on the substrate to form a cladding layer, such as by a conventional deposition process. Thereafter, a waveguide material is deposited on the cladding layer to form a waveguide layer, such as by a conventional deposition process. The input waveguide 112, waveguide arms 120, 130, and cascaded grating structures 114, 118 are then formed in the waveguide layer using standard microfabrication techniques, such as lithography, etching, and resist removal processes.

As described mentioned above, first waveguide grating structure 114 can be implemented as a grating-assisted contradirectional coupler that has a periodic grating structure, with a pi phase shift in a central portion thereof. The second waveguide grating structure 118 can similarly be implemented as a grating-assisted contradirectional coupler having a periodic grating structure, but without the pi phase shift. The waveguide grating structures 114, 118 can be formed with a pair of waveguides next to each other, in which periodic grating structures thereon are produced by a sidewall modulation of the waveguides. The stopbands of the waveguide grating structures 114, 118 can be passively aligned with each other by using the same waveguide width and grating period in these structures. This passive alignment of the stopbands allows waveguide platform 110 to be in operation, without the need for active heating or cooling, to obtain a single resonance frequency that is fed back to gain chip 102.

In fabricating waveguide grating structure 114 with the single defect cavity, the periodic grating structure is configured to produce a pi phase shift of the light, which is an abrupt change in a spatial pattern of the waveguide modulation, such that the periodic structure of the waveguide modulation is shifted in spatial phase by pi radians on either side of an interface. This generates a confined field of the light at a resonance wavelength, with the light circulating around the pi phase shift.

During operation of laser device 100, light emitted by gain chip 102 is directed along input waveguide 112 and split such that about half of the intensity of the light goes into first waveguide arm 120, and about half of the intensity of the light goes into second waveguide arm 130. The light going into first waveguide arm 120 travels along first waveguide branch 122 and into first waveguide grating structure 114 via input port 115. The light in first waveguide grating structure 114 comes into contact with the single defect cavity with the pi phase shift. This results in a narrowband resonance inside the stopband of first waveguide grating structure 114. The single resonance and the light outside of the stopband are sent from transmission port 116 of first waveguide grating structure 114 to second waveguide branch 124, which directs this light to input port 119 of second waveguide grating structure 118. The remainder of the light exits reflection port 117 of first waveguide grating structure 114 to third waveguide branch 126 and is discarded. The second waveguide grating structure 118 diffracts the received light from second waveguide branch 124, such that only the narrowband resonance of the light is sent from reflection port 121 back toward gain chip 102, through fourth waveguide branch 132 and input waveguide 112. The remainder of the received light from second waveguide branch 124, outside of the stopband, is passed out of second waveguide grating structure 118 through a drop port and discarded.

Also during operation, the light that initially splits into second waveguide arm 130 travels along fourth waveguide branch 132 and into second waveguide grating structure 118, which reflects the light within its stopband to first waveguide grating structure 114 through second waveguide branch 124. This light in first waveguide grating structure 114 comes into contact with the single defect cavity with the pi phase shift, resulting in the narrowband resonance inside the stopband being sent back toward gain chip 102, through first waveguide branch 122 and input waveguide 112. By splitting the light such that it travels in opposite directions around waveguide platform 110, with only the narrowband resonance sent back to gain chip 102, a standing wave cavity is created. Thereafter, laser light can be output from fifth waveguide branch 134 off of fourth waveguide branch 132, such as by a tap port.

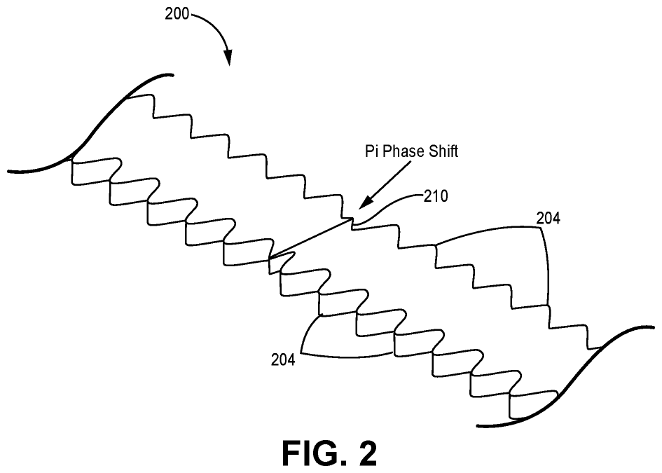

One example embodiment of a pi phase shift design 200, which can be employed in the single defect cavity, grating-assisted directional coupler, is shown in FIG. 2. The pi phase shift design 200 allows a selected wavelengths of light to be sent to a transmission port for further use, and all other wavelengths of light exit through a reflection port. The pi phase shift design 200 includes a periodic grating structure 204. In a central portion of periodic grating structure 204, a pi phase shift structure 210 is formed. There, the phase of the modulation employed to create grating structure 204 is configured to generate a tightly confined light field at the resonance wavelength, with the light circulating around the pi phase shift. The pi phase shift is an abrupt change in the phase of the modulation that defines the grating. The resonance wavelength can be modified by changing the period of grating structure 204, and the bandwidth can be optimized for specific application requirements.

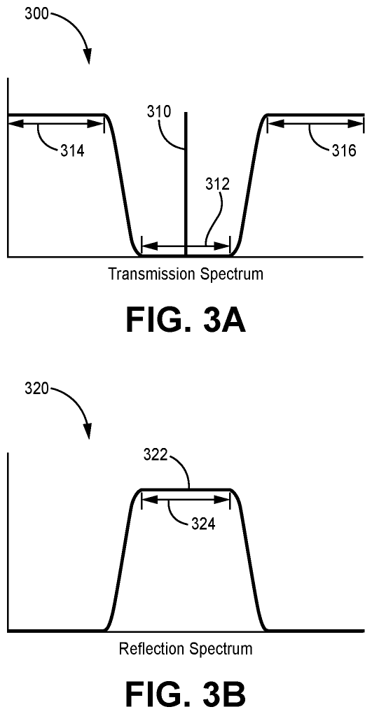

FIG. 3A is a graphical representation 300 of a transmission spectrum of light in a single defect cavity, such as in first waveguide grating structure 114, employed in an external cavity laser, such as laser device 100 of FIG. 1. As shown in FIG. 3A, the single defect cavity produces a single resonance frequency 310 within a stopband 312, and a set of passband frequencies 314, 316. For example, this transmission spectrum of light would be sent from transmission port 116 of first waveguide grating structure 114 to input port 119 of second waveguide grating structure 118, and the remaining wavelengths of light would exit through reflection port 117 of first waveguide grating structure 114.

FIG. 3B is a graphical representation 320 of a reflection spectrum of light in a filter grating, such as second waveguide grating structure 116, employed in an external cavity laser, such as laser device 100. As shown in FIG. 3B, the filter grating diffract/reflects a narrowband resonance 322 within a stopband 324, which overlaps with stopband 312 (FIG. 3A). For example, the light within this reflection spectrum, which would include only single resonance frequency 310 from first waveguide grating structure 114, would be sent from reflection port 121 of second waveguide grating structure 118 back to gain chip 102, and the remaining wavelengths of light would exit through a drop port of second waveguide grating structure 118.

Thus, as illustrated in FIGS. 3A and 3B, the single defect cavity grating and filter grating cooperate to yield a single resonance frequency, which is used in a feedback to the gain chip, producing a self-injection lock for the external cavity laser.

### Example Embodiments

Example 1 includes a laser device comprising: a gain chip configured to emit a beam of light; and a photonics chip optically coupled to the gain chip, the photonics chip comprising: a waveguide platform including an input waveguide, which is optically coupled to the gain chip, the input waveguide in optical communication with a cascaded arrangement of waveguide grating structures on the waveguide platform, the waveguide grating structures comprising: a first waveguide grating structure configured to produce a single resonance frequency within a stopband; and a second waveguide grating structure in optical communication with the first waveguide grating structure, the second waveguide grating structure configured to diffract a narrowband resonance, overlapping with the stopband of the first waveguide grating structure, back toward the gain chip, while passing any light outside of the stopband of the first waveguide grating structure out of the waveguide platform; wherein the first and second waveguide grating structures cooperate to yield a single resonance frequency of the light that feeds back into the gain chip to produce a self-injection lock for the laser device.
Example 2 includes the laser device of Example 1, wherein the gain chip comprises a reflective semiconductor optical amplifier (RSOA).
Example 3 includes the laser device of any of Examples 1-2, wherein the gain chip comprises an indium phosphide (InP) based RSOA.
Example 4 includes the system of any of Examples 1-3, wherein the photonics chip comprises a silicon photonics integrated circuit.
Example 5 includes the laser device of any of Examples 1-4, wherein the waveguide platform includes a substrate layer, a cladding layer over the substrate layer, and a waveguide layer over the cladding layer, wherein the waveguide layer defines the input waveguide and the cascaded arrangement of waveguide grating structures on the waveguide platform.
Example 6 includes the laser device of any of Examples 1-5, wherein the first waveguide grating structure includes a single defect cavity Bragg grating configured to operate as a resonator.
Example 7 includes the laser device of any of Examples 1-6, wherein the first waveguide grating structure comprises a grating-assisted contradirectional coupler that has a periodic grating structure configured to produce a pi phase shift in a central portion thereof.
Example 8 includes the laser device of Example 7, wherein the pi phase shift is an abrupt change in a spatial pattern of waveguide modulation, such that a periodic structure of the waveguide modulation is shifted in spatial phase by pi radians on either side of an interface, which generates a confined field of the light at a resonance wavelength, with the light circulating around the pi phase shift.
Example 9 includes the laser device of any of Examples 1-8, wherein the second waveguide grating structure comprises a filter Bragg grating.
Example 10 includes the laser device of any of Examples 1-9, wherein the second waveguide grating structure comprises a grating-assisted contradirectional coupler that has a periodic grating structure without a pi phase shift.
Example 11 includes the laser device of any of Examples 1-10, wherein the input waveguide is split between a first waveguide arm and a second waveguide arm on the waveguide platform.
Example 12 includes the laser device of Example 11, wherein the first waveguide arm comprises: a first waveguide branch coupled between the input waveguide and an input port of the first waveguide grating structure; a second waveguide branch coupled between a transmission port of the first waveguide grating structure and an input port of the second waveguide grating structure; and a third waveguide branch coupled with a reflection port of the waveguide first grating structure.
Example 13 includes the laser device of Example 12, wherein the second waveguide arm comprises: a fourth waveguide branch coupled between the input waveguide and a reflection port of the second waveguide grating structure; and a fifth waveguide branch split off from the fourth waveguide branch to a laser output.
Example 14 includes the laser device of Example 13, wherein the first waveguide grating structure includes a single defect cavity configured to produce a transmission spectrum of the light comprising the single resonance frequency within the stopband and a set of passband frequencies.
Example 15 includes the laser device of Example 14, wherein the transmission spectrum of the light is sent from the transmission port of the first waveguide grating structure to the input port of the second waveguide grating structure, with remaining wavelengths of the light exiting through the reflection port of the first waveguide grating structure.
Example 16 includes the laser device of Example 15, wherein the second waveguide grating structure includes a filter grating configured to produce a reflection spectrum of the light comprising a narrowband resonance within a stopband that overlaps with the stopband of the first waveguide grating structure.
Example 17 includes the laser device of Example 16, wherein the light within the reflection spectrum, including only the single resonance frequency from the first waveguide grating structure, is sent from the reflection port of the second waveguide grating structure back to the gain chip, with remaining wavelengths of light exiting through a drop port of the second waveguide grating structure.
Example 18 includes a method of producing an external cavity laser, the method comprising: fabricating a waveguide platform including an input waveguide and a cascaded arrangement of waveguide grating structures in optical communication with the input waveguide, the waveguide grating structures formed by a process comprising: forming a first waveguide grating structure including a single defect cavity that produces a single resonance frequency within a stopband; forming a second waveguide grating structure including a filter grating that diffracts a narrowband resonance, overlapping with the stopband of the first waveguide grating structure, the second waveguide grating structure in optical communication with the first waveguide grating structure; optically coupling a photonics chip with the waveguide platform; optically coupling a gain chip to the photonics chip such that the input waveguide is optically coupled to the gain chip; wherein the first and second waveguide grating structures cooperate to yield a single resonance frequency of light that feeds back into the gain chip to produce a self-injection lock for the external cavity laser.
Example 19 includes the method of Example 18, wherein: the first waveguide grating structure comprises a grating-assisted contradirectional coupler that has a periodic grating structure configured to produce a pi phase shift in a central portion thereof; and the second waveguide grating structure comprises a grating-assisted contradirectional coupler that has a periodic grating structure without a pi phase shift.
Example 20 includes the method of any of Examples 18-19, wherein the waveguide platform includes a substrate layer, a cladding layer formed over the substrate layer, and a waveguide layer formed over the cladding layer, wherein the waveguide layer defines the input waveguide and the cascaded arrangement of waveguide grating structures on the waveguide platform.

From the foregoing, it will be appreciated that, although specific embodiments have been described herein for purposes of illustration, various modifications may be made without deviating from the scope of the disclosure. Thus, the described embodiments are to be considered in all respects only as illustrative and not restrictive. In addition, all changes that come within the meaning and range of equivalency of the claims are to be embraced within their scope.

What is claimed is:

1. A laser device comprising:
a gain chip configured to emit a beam of light; and
a photonics chip optically coupled to the gain chip, the photonics chip comprising:
a waveguide platform including an input waveguide, which is optically coupled to the gain chip, the input waveguide in optical communication with a cascaded arrangement of waveguide grating structures on the waveguide platform, the waveguide grating structures comprising:
a first waveguide grating structure configured to produce a single resonance frequency within a stopband; and
a second waveguide grating structure in optical communication with the first waveguide grating structure, the second waveguide grating structure configured to diffract a narrowband resonance, overlapping with the stopband of the first waveguide grating structure, back toward the gain chip, while passing any light outside of the stopband of the first waveguide grating structure out of the waveguide platform;
wherein the first and second waveguide grating structures cooperate to yield a single resonance frequency of the light that feeds back into the gain chip to produce a self-injection lock for the laser device.

2. The laser device of claim 1, wherein the gain chip comprises a reflective semiconductor optical amplifier (RSOA).

3. The laser device of claim 1, wherein the gain chip comprises an indium phosphide (InP) based RSOA.

4. The system of claim 1, wherein the photonics chip comprises a silicon photonics integrated circuit.

5. The laser device of claim 1, wherein the waveguide platform includes a substrate layer, a cladding layer over the substrate layer, and a waveguide layer over the cladding layer, wherein the waveguide layer defines the input waveguide and the cascaded arrangement of waveguide grating structures on the waveguide platform.

6. The laser device of claim 1, wherein the first waveguide grating structure includes a single defect cavity Bragg grating configured to operate as a resonator.

7. The laser device of claim 1, wherein the first waveguide grating structure comprises a grating-assisted contradirectional coupler that has a periodic grating structure configured to produce a pi phase shift in a central portion thereof.

8. The laser device of claim 7, wherein the pi phase shift is an abrupt change in a spatial pattern of waveguide modulation, such that a periodic structure of the waveguide modulation is shifted in spatial phase by pi radians on either side of an interface, which generates a confined field of the light at a resonance wavelength, with the light circulating around the pi phase shift.

9. The laser device of claim 1, wherein the second waveguide grating structure comprises a filter Bragg grating.

10. The laser device of claim 1, wherein the second waveguide grating structure comprises a grating-assisted contradirectional coupler that has a periodic grating structure without a pi phase shift.

11. The laser device of claim 1, wherein the input waveguide is split between a first waveguide arm and a second waveguide arm on the waveguide platform.

12. The laser device of claim 11, wherein the first waveguide arm comprises:
a first waveguide branch coupled between the input waveguide and an input port of the first waveguide grating structure;
a second waveguide branch coupled between a transmission port of the first waveguide grating structure and an input port of the second waveguide grating structure; and
a third waveguide branch coupled with a reflection port of the waveguide first grating structure.

13. The laser device of claim 12, wherein the second waveguide arm comprises:
a fourth waveguide branch coupled between the input waveguide and a reflection port of the second waveguide grating structure; and
a fifth waveguide branch split off from the fourth waveguide branch to a laser output.

14. The laser device of claim 13, wherein the first waveguide grating structure includes a single defect cavity configured to produce a transmission spectrum of the light comprising the single resonance frequency within the stopband and a set of passband frequencies.

15. The laser device of claim 14, wherein the transmission spectrum of the light is sent from the transmission port of the first waveguide grating structure to the input port of the second waveguide grating structure, with remaining wavelengths of the light exiting through the reflection port of the first waveguide grating structure.

16. The laser device of claim 15, wherein the second waveguide grating structure includes a filter grating configured to produce a reflection spectrum of the light comprising a narrowband resonance within a stopband that overlaps with the stopband of the first waveguide grating structure.

17. The laser device of claim 16, wherein the light within the reflection spectrum, including only the single resonance frequency from the first waveguide grating structure, is sent from the reflection port of the second waveguide grating structure back to the gain chip, with remaining wavelengths of light exiting through a drop port of the second waveguide grating structure.

18. A method of producing an external cavity laser, the method comprising:
fabricating a waveguide platform including an input waveguide and a cascaded arrangement of waveguide grating structures in optical communication with the input waveguide, the waveguide grating structures formed by a process comprising:
forming a first waveguide grating structure including a single defect cavity that produces a single resonance frequency within a stopband;
forming a second waveguide grating structure including a filter grating that diffracts a narrowband resonance, overlapping with the stopband of the first waveguide grating structure, the second waveguide grating structure in optical communication with the first waveguide grating structure;
optically coupling a photonics chip with the waveguide platform;
optically coupling a gain chip to the photonics chip such that the input waveguide is optically coupled to the gain chip;
wherein the first and second waveguide grating structures cooperate to yield a single resonance frequency of light that feeds back into the gain chip to produce a self-injection lock for the external cavity laser.

19. The method of claim 18, wherein:
the first waveguide grating structure comprises a grating-assisted contradirectional coupler that has a periodic grating structure configured to produce a pi phase shift in a central portion thereof; and
the second waveguide grating structure comprises a grating-assisted contradirectional coupler that has a periodic grating structure without a pi phase shift.

20. The method of claim 18, wherein the waveguide platform includes a substrate layer, a cladding layer formed over the substrate layer, and a waveguide layer formed over the cladding layer, wherein the waveguide layer defines the input waveguide and the cascaded arrangement of waveguide grating structures on the waveguide platform.
